(19) United States
(12) Patent Application Publication
(10) Pub. No.: US 2006/0105533 A1
(43) Pub. Date: May 18, 2006

(54) Method for engineering hybrid orientation/material semiconductor substrate

(76) Inventors: Yung Fu Chong, Singapore (SG); Liang Choo Hsia, Singapore (SG); Chew Hoe Ang, Singapore (SG)

Correspondence Address: WILLIAM STOFFEL, PMB 455, 1735 MARKET ST. - STE. A, PHILADELPHIA, PA, 19103-7502, US

(21) Appl. No.: 10/990,180

(22) Filed: Nov. 16, 2004

(51) Int. Cl. H01L 21/8228

(52) U.S. Cl. 438/322

(57) ABSTRACT

The embodiments provide a structure and a method of manufacturing a semiconductor structure that has a different material in the area where PMOS devices will be formed than in the area where NMOS devices will be formed which is characterized as follows. An embodiment comprises the following steps. A substrate is provided. The substrate has a NMOS area and a PMOS area. We form a NMOS mask over the NMOS area. We form a first semiconductor layer over the PMOS area. We remove the mask. We form a second semiconductor layer over the NMOS area. Then we form an isolation region in the substrate between at least portions of the NMOS and the PMOS areas. We form PMOS devices in the PMOS area and form NMOS devices in the NMOS area.

### BACKGROUND OF INVENTION

1) Field of the Invention

This invention relates generally to the structure and fabrication of semiconductor structures and more particularly to the fabrication of a semiconductor structure with different materials in the PMOS and NMOS active areas.

2) Description of the Prior Art

Mobility degradation is a major concern for transistor scaling due to higher channel doping, higher vertical field, and the use of high-k gate dielectric materials. In addition, due to the different substrate requirements for carrier mobility enhancement in NMOS and PMOS devices, the current technology for forming CMOS devices on the same substrate/platform will face severe limitations in the future. For e.g., it is known that hole mobility can be enhanced with the use of a silicon-germanium (SiGe) channel.

The relevant technical developments in the patent literature can be gleaned by considering the following.

U.S. Pat. No. 6,774,409 Baba, et al. Aug. 10, 2004—Semiconductor device with NMOS including Si:C channel region and/or PMOS including SiGe channel region.

U.S. Pat. No. 6,743,291—Ang, et al. Jun. 1, 2004—Chartered—Method of fabricating a CMOS device with integrated super-steep retrograde twin wells using double selective epitaxial growth.

U.S. Pat. No. 6,555,874—Hsu et al.—teaches a CMOS formed on a SOI and a SIGE HBT formed on the substrate.

US Patent Application 20030057487 A1—Yamada, Takashi; et al. Mar. 27, 2003—Semiconductor chip having multiple functional blocks integrated in a single chip and method for fabricating the same. A semiconductor chip comprises a base substrate, a bulk device region having a bulk growth layer on a part of the base substrate, an SOI device region having a buried insulator on the base substrate and a silicon layer on the buried insulator, and a boundary layer located at the boundary between the bulk device region and the SOI device region. The bulk device region has a first device-fabrication surface in which a bulk device is positioned on the bulk growth layer. The SOI device region has a second device-fabrication surface in which an SOI device is positioned on the silicon layer. The first and second device-fabrication surfaces are positioned at a substantially uniform level.

US Patent Application 20040121507-A1—Bude, et al. Jun. 24, 2004—Semiconductor devices with reduced active region defects and unique contacting schemes.

US Patent Application 20030140317-A1—Brewer, et al. Jul. 24, 2003—Process for assembling three-dimensional systems on a chip and structure thus obtained.

U.S. Pat. No. 5,461,250—Burghartz, et al.—SiGe thin film or SOI MOSFET and method for making the same.

U.S. Pat. No. 6,521,883B2—Isomura shows a substrate with a overlying conductive layer.

### SUMMARY OF THE INVENTION

The embodiments of the present invention provides a structure and a method of manufacturing a semiconductor structure that has a different material in the area where PMOS devices will be formed than in the area where NMOS devices will be formed which is characterized as follows.

An example embodiment comprises the following. We provide a substrate. The substrate has a NMOS area and a PMOS area. We form a first semiconductor layer over the PMOS area. We then form a second semiconductor layer over the NMOS area. We form an isolation region in the substrate between at least portions of the NMOS and the PMOS areas. We form PMOS devices in the PMOS area and form NMOS devices in the NMOS area.

In a first option, the substrate is comprised of Si with a crystal orientation of (100); the first semiconductor layer is comprised of SiGe and the second semiconductor layer is comprised of Si with an orientation of (100).

In a second option, the substrate is comprised of Si with a crystal orientation of (110); the first semiconductor layer is comprised of (110) Si and the second semiconductor layer is comprised of Si with an orientation of (100).

In a third option, the substrate is comprised of Si with a crystal orientation of (100); the first semiconductor layer is comprised of SiGe and the second semiconductor layer is comprised of SiGe.

In a fourth option, the substrate is comprised of Si with a crystal orientation of (110); the first semiconductor layer is comprised of Si with a crystal orientation of (110) and the second semiconductor layer is comprised of SiGe.

In a fifth option, the substrate is comprised of Si with a crystal orientation of (100); the first semiconductor layer is comprised of Si with a crystal orientation of (110) and the second semiconductor layer is comprised of Si with a crystal orientation of (100).

Another embodiment is a semiconductor structure; comprised of: a substrate; the substrate has a NMOS area and a PMOS area; a first semiconductor layer over the PMOS area; a second semiconductor layer over the NMOS area; an isolation region in the substrate between at least portions of the NMOS and the PMOS areas; PMOS devices in the PMOS area and forming NMOS devices in the NMOS area.

Another embodiment is a method of fabrication of a semiconductor structure; comprises the following steps. A substrate is provided. The substrate has a NMOS area and a PMOS area. We form a NMOS mask over the NMOS area. We form a first semiconductor layer (e.g., silicon-germanium) over the PMOS area. We remove the mask. We form a silicon layer over the NMOS area. Then any silicon layer over the PMOS area is removed. Then we form an isolation region in the substrate between at least portions of the NMOS and the PMOS areas. We form PMOS devices in the PMOS area and form NMOS devices in the NMOS area.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1 through 6 are cross sectional views for illustrating a structure and method for manufacturing a semiconductor structure according to an example embodiment of the present invention.

### DETAILED DESCRIPTION OF THE PREFERRED EMBODIMENTS

The present invention will be described in detail with reference to the accompanying drawings. The present invention provides a method of forming a semiconductor structure with different materials in the PMOS and NMOS active areas.

A. Substrate

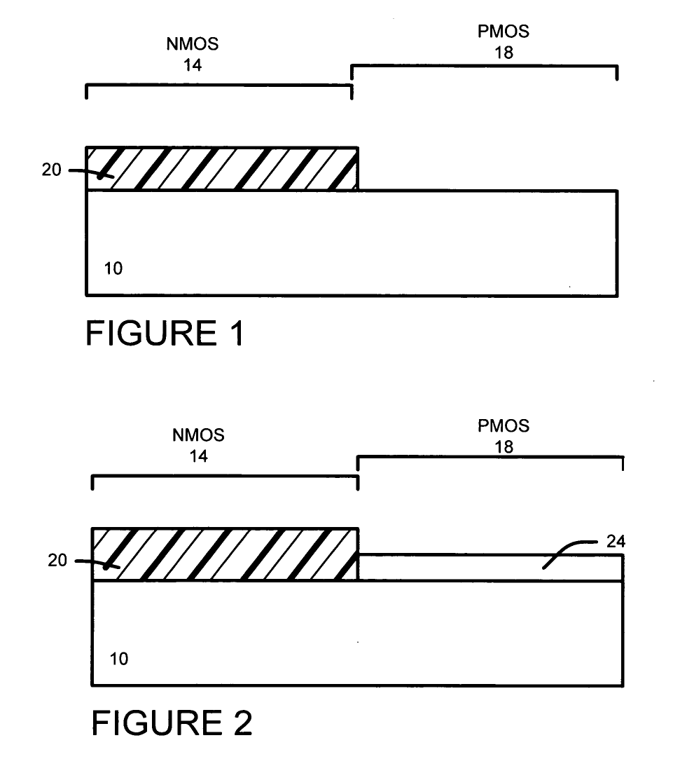

Referring to FIG. 1, we provide a substrate 10. The substrate has a NMOS area 14 and a PMOS area 18.

The substrate 10 can be comprised of a silicon wafer, a silicon on insulator substrate (SOI), strained silicon or SiGe.

The substrate 10 can be comprised of silicon with a (010) or (110) or (100) orientation. It is preferable that the substrate 10 comprises silicon with a (100) orientation. The substrate preferably has thickness between 500 and 1000 micrometers (um). The substrate is preferably doped with P or B at a concentration between 1×10¹⁵ and 1×10¹⁶/cm³.

The substrate can also be comprised of a SOI substrate. The SOI substrate comprised of a low layer, an insulating layer, and an upper silicon layer. The upper silicon layer can be comprised of (010), (110) or (100) orientation.

B. Form a NMOS Mask

Still referring to FIG. 1, we form a NMOS mask 20 over the NMOS area 14. The mask 20 can be comprised of oxide or silicon nitride or silicon oxynitride.

C. Form a First Semiconductor Layer Over the PMOS Area

As shown in FIG. 2, we form a first semiconductor layer 24 over the PMOS area 18. The first semiconductor layer 24 is preferably formed by a selective epitaxial growth process (SEG) only over the PMOS area 18.

The first semiconductor layer 24 has a thickness between 200 and 2000 angstroms.

The first semiconductor layer 24 is preferably comprised of SiₓGe₁₋ₓ where x is preferably between 0.5 and 0.9. It is optional to have a thin strained silicon layer over the SiGe layer. Depending on the application of the device, the silicon-germanium layer 24 can also be strained.

The first semiconductor layer is not limited to SiGe, but can include growing of (110) silicon over the PMOS active regions. This can be achieved by either surface treatment of the (100) silicon substrate or by advanced epitaxial techniques. The (110) silicon layer 24 can have a thickness between 200 and 2000 angstroms. The substrate is preferably doped with P or B at a concentration between 1×10¹⁵ and 1×10¹⁶/cm³. The silicon body may be subjected to a heat treatment to ensure a good interface between the (110) silicon and the (100) Si substrate 10. For the heat treatment, the temperature range is 950 to 1100° C. and the duration is in the range of 30 min to 6 hrs.

D. Remove the NMOS Mask

Next, we remove the mask 20, preferably by an etch. The etch can either be a dry etch or an isotropic wet etch. A wet etch is preferred.

E. Form a Second Semiconductor Layer 28 Over the NMOS Area 14

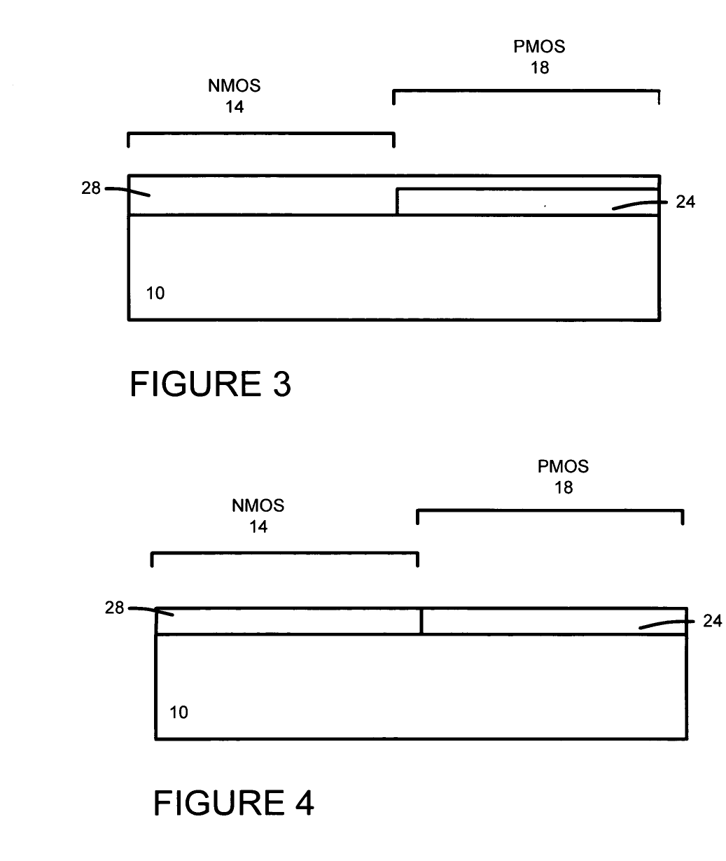

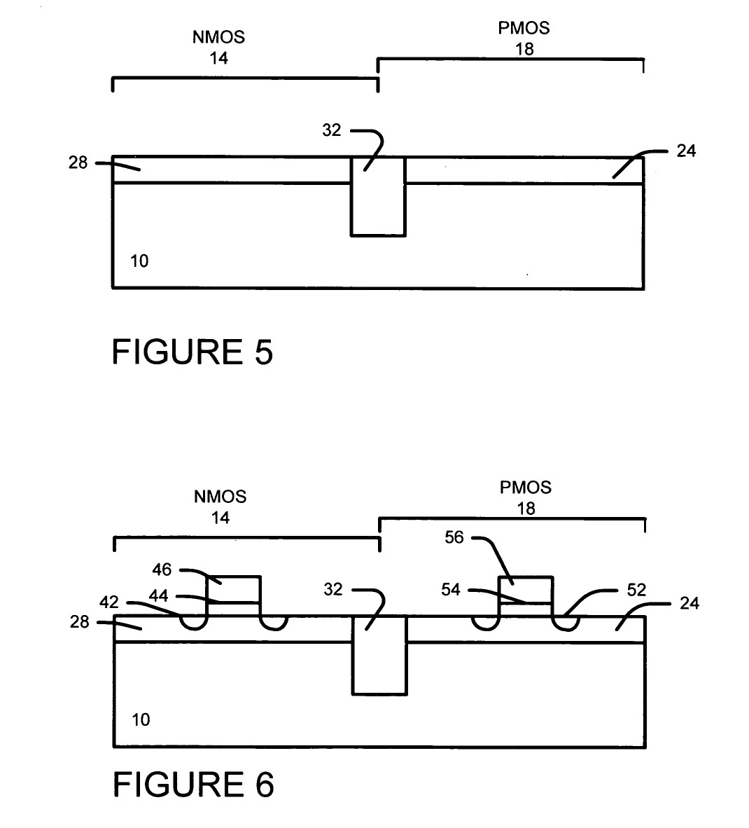

As shown in FIG. 3, we form a second semiconductor layer 28 over the NMOS area 14. The semiconductor layer 28 is preferably formed by a selective epitaxial growth process (SEG) only over the NMOS area 14.

The second semiconductor layer 28 preferably has a thickness between 200 and 2500 angstroms.

The second semiconductor layer 28 is preferably comprised of (100) Si, and preferably has the same crystal orientation as the substrate 10. Depending on the application of the device and also on the starting material/substrate, the second semiconductor layer 28 is not limited to (100) Si.

Below is a table with some of the possible combination of compositions of the first and second semiconductor layers.

TABLE
Options of combination of compositions of the
first 24 and second 28 semiconductor layers.

| | 1^{st} semiconductor | 2^{nd} semiconductor | |
|---|---|---|---|
| Option | layer (24) | layer 28 | Substrate 10 |
| 1 | SiGe | Si (100) | Si (100) |
| 2 | Si (110) | Si (100) | Si (110) |
| 3 | SiGe | SiGe | Si (100) |
| 4 | Si (110) | SiGe | Si (110) |
| 5 | Si (110) | Si (100) | Si (100) |

Any of the layers could be carbon doped and/or strained. The first and/or second semiconductor layers could be comprised of two more layers. For example, it is possible to have a thin strained silicon layer over the SiGe layer.

The option with the carbon doped first and second semiconductor layers (for both Si or SiGe) reduces the transient enhanced diffusion (TED) of boron or suppress boron outdiffusion

A option with the carbon doped first and second semiconductor layers can further enhance carrier mobility in the channel.

F. Planarizing the Semiconductor Layers

As shown in FIG. 4, we preferably planarize the semiconductor layers 24 and 28 for subsequent active area definition/patterning. The step of planarizing the semiconductor layers preferably comprises a chemical-mechanical polish (CMP) process. During the CMP process, the silicon layer 28 over the PMOS area 14 may be removed. However, it is optional that a thin layer of Si cap layer can remain on the PMOS region to have better gate oxide quality.

G. Form an Isolation Region

We preferably form an isolation region 32 in the substrate between at least portions of the NMOS and the PMOS areas. The isolation region should preferably be formed using shallow trench isolation (STI) technique. The isolation region also helps to prevent Ge diffusion from SiGe layer 24 during subsequent thermal cycles.

H. Form PMOS Devices and NMOS Devices

Referring to FIG. 6, we form PMOS devices in the PMOS area 18 and forming NMOS devices in the NMOS area 14. FIG. 6 shows a NMOS transistor comprised of S/D 42, gate dielectric 44 and gate 46 and a PMOS transistor comprised of S/D 52, gate dielectric 54 and gate 56.

I. Non-Limiting Example Embodiments

The example embodiments of the present invention will eliminate the problem of forming CMOS devices (with different substrate requirements) on the same substrate/platform. Also, the example embodiment methods help to tailor the various device performances to different substrate material and orientations.

For the embodiment, the hole mobility is more than doubled on (110) silicon substrates with current flow direction along <110> compared with conventional (100) substrates. However electron mobility is the highest on (100) substrates.

Although this invention has been described relative to specific insulating materials, conductive materials and apparatuses for depositing and etching these materials, it is not limited to the specific materials or apparatuses but only to their specific characteristics; and other materials and apparatus can be substituted as is well understood by those skilled in the microelectronics arts after appreciating the present invention

Unless explicitly stated otherwise, each numerical value and range should be interpreted as being approximate as if the word about or approximately preceded the value of the value or range.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

1. A method of fabrication of a semiconductor structure; comprising the steps of:
a) providing a substrate; said substrate has a NMOS area and a PMOS area;
b) forming a first semiconductor layer over said PMOS area;
c) forming a second semiconductor layer over said NMOS area.

2. The method of claim 1 which further includes; planarizing the first and second semiconductor layers using a chemical-mechanical polish process; and any of the second semiconductor layer over the PMOS area is removed.

3. The method of claim 1 wherein said first semiconductor layer is comprised of SiGe and said second semiconductor layer is comprised of silicon and said substrate is comprised essentially of silicon.

4. The method of claim 1 wherein said first semiconductor layer is comprised of (110) silicon; said second semiconductor layer is comprised of silicon and said substrate is comprised essentially of silicon.

5. The method of claim 1 wherein said substrate is comprised of Si with a crystal orientation of (100); the first semiconductor layer is comprised of SiGe and the second semiconductor layer is comprised of Si with an orientation of (100).

6. The method of claim 1 wherein said substrate is comprised of Si with a crystal orientation of (110); the first semiconductor layer is comprised of Si with an orientation of (110) and the second semiconductor layer is comprised of Si with an orientation of (100).

7. The method of claim 1 wherein said substrate is comprised of Si with a crystal orientation of (100); the first semiconductor layer is comprised of SiGe and the second semiconductor layer is comprised of SiGe.

8. The method of claim 1 wherein said substrate is comprised of Si with a crystal orientation of (110); the first semiconductor layer is comprised of Si with a crystal orientation of (110) and the second semiconductor layer is comprised of SiGe.

9. The method of claim 1 wherein said substrate is comprised of Si with a crystal orientation of (100); the first semiconductor layer is comprised of (110) Si and the second semiconductor layer is comprised of Si with an orientation of (100).

10. A method of fabrication of a semiconductor structure; comprising the steps of:
a) providing a substrate; said substrate has a NMOS area and a PMOS area;
b) forming a NMOS mask over said NMOS area;
c) forming a first semiconductor layer over said PMOS area;
d) removing said NMOS mask;
e) forming a second semiconductor layer over at least said NMOS area; and
f) planarizing the first and second semiconductor layers.

11. The method of claim 10 which further includes:
forming an isolation region in said substrate between at least portions of said NMOS and said PMOS areas;
forming PMOS devices in said PMOS area and forming NMOS devices in said NMOS area.

12. The method of claim 10 wherein said first semiconductor layer is comprised of SiGe and said second semiconductor layer is comprised of silicon and said substrate is comprised essentially of silicon.

13. The method of claim 10 wherein said first semiconductor layer is comprised of (110) silicon; said second semiconductor layer is comprised of silicon and said substrate is comprised essentially of silicon.

14. The semiconductor of claim 10 wherein said first semiconductor layer is comprised of a Si layer over a SiGe layer and said second semiconductor layer is comprised of silicon and said substrate is comprised essentially of silicon.

15. The method of claim 10 wherein said substrate is comprised of Si with a crystal orientation of (100); the first semiconductor layer is comprised of SiGe and the second semiconductor layer is comprised of Si with an orientation of (100).

16. The method of claim 10 wherein said substrate is comprised of Si with a crystal orientation of (110); the first semiconductor layer is comprised of (110) Si and the second semiconductor layer is comprised of Si with an orientation of (100).

17. The method of claim 10 wherein said substrate is comprised of Si with a crystal orientation of (100); the first semiconductor layer is comprised of SiGe and the second semiconductor layer is comprised of SiGe.

18. The method of claim 10 wherein said substrate is comprised of Si with a crystal orientation of (110); the first semiconductor layer is comprised of Si with a crystal orientation of (110) and the second semiconductor layer is comprised of SiGe.

19. The method of claim 10 wherein said substrate is comprised of Si with a crystal orientation of (100); the first semiconductor layer is comprised of Si with a crystal orientation of (110) and the second semiconductor layer is comprised of Si with a crystal orientation of (100).

20. The method of claim 10 wherein said substrate comprised of a material selected from the group consisting of silicon wafer, Silicon on insulator substrate, strained silicon, and SiGe.

21. The method of claim 10 wherein said substrate comprised of a SOI substrate; said SOI substrate comprised of a lower layer, an insulating layer, and an upper silicon layer.

22. The method of claim 10 wherein the first semiconductor layer is comprised of SiₓGe₁₋ₓ where x is between 0.5 and 0.9.

23. A method of fabrication of a semiconductor structure; comprising the steps of:
a) providing a substrate; said substrate has a NMOS area and a PMOS area;
b) forming a NMOS mask over said NMOS area;
c) forming a first semiconductor layer over said PMOS area;
(1) said first semiconductor layer is comprised of silicon-germanium or silicon with a (110) crystal orientation;
d) removing said NMOS mask;
e) forming a second semiconductor layer over said NMOS area; said second semiconductor layer is comprised of crystalline silicon;
f) planarizing using a chemical-mechanical polish process the first and second semiconductor layers; the second semiconductor layer over the PMOS area is removed;
g) forming an isolation region in said substrate between at least portions of said NMOS and said PMOS areas;
h) forming PMOS devices in said PMOS area and forming NMOS devices in said NMOS area.

24. The method of claim 23 wherein said substrate comprised of a material selected from the group consisting of silicon wafer, Silicon on insulator substrate, strained silicon, and SiGe.

25. The method of claim 23 wherein said substrate is comprised of silicon having a (100) orientation; said substrate having a thickness between 500 and 1000 micrometers.

26. The method of claim 23 wherein said substrate comprised of a SOI substrate; said SOI substrate comprised of a lower layer, an insulating layer, and an upper silicon layer.

27. The method of claim 23 wherein said substrate is comprised of Si with a crystal orientation of (100); the first semiconductor layer is comprised of SiGe and the second semiconductor layer is comprised of Si with an orientation of (100).

28. The method of claim 23 wherein said substrate is comprised of Si with a crystal orientation of (110); the first semiconductor layer is comprised of Si with a crystal orientation of (110) and the second semiconductor layer is comprised of Si with an orientation of (100).

29. The method of claim 23 wherein said substrate is comprised of Si with a crystal orientation of (100); the first semiconductor layer is comprised of SiGe and the second semiconductor layer is comprised of SiGe.

30. The method of claim 23 wherein said substrate is comprised of Si with a crystal orientation of (110); the first semiconductor layer is comprised of Si with a crystal orientation of (110) and the second semiconductor layer is comprised of SiGe.

31. The method of claim 23 wherein said substrate is comprised of Si with a crystal orientation of (100); the first semiconductor layer is comprised of Si with a crystal orientation of (110) and the second semiconductor layer is comprised of Si with a crystal orientation of (100).

32. A semiconductor structure; comprising of:
a) a substrate; said substrate has a NMOS area and a PMOS area;
b) a first semiconductor layer over said PMOS area;
c) a second semiconductor layer over said NMOS area.

33. The semiconductor of claim 32 which further includes: an isolation region in said substrate between at least portions of said NMOS area and said PMOS area;
PMOS devices in said PMOS area and NMOS devices in said NMOS area.

34. The semiconductor of claim 32 wherein said first semiconductor layer is comprised of SiGe and said second semiconductor layer is comprised of silicon and said substrate is comprised essentially of silicon.

35. The semiconductor of claim 32 wherein said first semiconductor layer is comprised of a Si layer over a SiGe layer and said second semiconductor layer is comprised of silicon and said substrate is comprised essentially of silicon.

36. The semiconductor of claim 32 wherein said first semiconductor layer is comprised of (110) silicon; said second semiconductor layer is comprised of silicon and said substrate is comprised essentially of silicon.

37. The semiconductor of claim 32 wherein said substrate is comprised of Si with a crystal orientation of (100); the first semiconductor layer is comprised of SiGe and the second semiconductor layer is comprised of Si with an orientation of (100).

38. The semiconductor of claim 32 wherein said substrate is comprised of Si with a crystal orientation of (110); the first semiconductor layer is comprised of (110) Si and the second semiconductor layer is comprised of Si with an orientation of (100).

39. The semiconductor of claim 32 wherein said substrate is comprised of Si with a crystal orientation of (100); the first semiconductor layer is comprised of SiGe and the second semiconductor layer is comprised of SiGe.

40. The semiconductor of claim 32 wherein said substrate is comprised of Si with a crystal orientation of (110); the first semiconductor layer is comprised of (110) Si and the second semiconductor layer is comprised of SiGe.

41. The semiconductor of claim 32 wherein said substrate is comprised of Si with a crystal orientation of (100); the first semiconductor layer is comprised of Si with a crystal orientation of (110) and the second semiconductor layer is comprised of Si with a crystal orientation of (100).

42. The method of claim 1 which further includes:
forming an isolation region in said substrate between at least portions of said NMOS and said PMOS areas;
forming PMOS devices in said PMOS area and forming NMOS devices in said NMOS area.
